(19) United States
(12) Patent Application Publication
(10) Pub. No.: US 2009/0179294 A1
(43) Pub. Date: Jul. 16, 2009

(54) IMAGE SENSOR AND METHOD FOR MANUFACTURING THE SAME

(76) Inventors: Jeong-Yel Jang, Eumseong-gun (KR); Woo-Seok Hyun, Seo-gu (KR)

Correspondence Address: SHERR & VAUGHN, PLLC, 620 HERNDON PARKWAY, SUITE 200, HERNDON, VA, 20170, US

(21) Appl. No.: 12/344,439

(22) Filed: Dec. 26, 2008

(30) Foreign Application Priority Data
Dec. 27, 2007 (KR) 10-2007-0139461
Jul. 14, 2008 (KR) 10-2008-0068268

(51) Int. Cl. H01L 31/102; H01L 21/50

(52) U.S. Cl. 257/461; 438/98; 257/E31.055; 257/E21.499

(57) ABSTRACT

An image sensor includes a readout circuitry, a first substrate, a first interlayer dielectric, a metal interconnection, a top metal, and an image sensing device. The readout circuitry is formed on and/or over the first substrate and the first interlayer dielectric is formed on and/or over the first substrate. The metal interconnection is formed in the interlayer dielectric and electrically connected to the readout circuitry. The top metal is formed on and/or over the metal interconnection and the image sensing device is formed on and/or over the top metal.

The present application claims priority under 35 U.S.C. § 119 to Korean Patent Application No. 10-2007-0139461 (filed Dec. 27, 2007) and Korean Patent Application No. 10-2008-0068268 (filed Jul. 14, 2008), which are hereby incorporated by reference in their entireties.

### BACKGROUND

An image sensor is a semiconductor device for converting an optical image into an electrical signal. Image sensors may be generally classified as a charge coupled device (CCD) image sensor or complementary metal oxide silicon (CMOS) image sensor (CIS). During the fabrication of image sensors, a photodiode may be formed in a substrate using ion implantation. As the size of a photodiode is reduced for the purpose of increasing the number of pixels without increasing chip size, the area of a light receiving portion is also reduced, thereby resulting in a reduction in image quality.

However, because a stack height does not reduce as much as the reduction in the area of the light receiving portion, the number of photons incident to the light receiving portion may also reduced due to diffraction of light, known as the “airy disk.” Related image sensors may attempt to form a photodiode using amorphous silicon (Si), or forming a readout circuitry in a silicon (Si) substrate using a method such as wafer-to-wafer bonding, and forming a photodiode on and/or over the readout circuitry. The photodiode may be connected with the readout circuitry through a metal interconnection. A bonding failure between the metal interconnection and the photodiode may occur and cause a problem in the electrical and physical bonding force. Because both the source and the drain on both sides of the transfer transistor are heavily doped with N-type impurities, a charge sharing phenomenon may occur. When the charge sharing phenomenon occurs, the sensitivity of an output image is reduced and an image error may be generated. Also, because a photo charge may not readily move between the photodiode and the readout circuitry, a dark current is generated and/or saturation and sensitivity is reduced.

### SUMMARY

Embodiments relate to an image sensor and a manufacturing method thereof that maximize a physical and electrical bonding force between an image sensing device and a metal interconnection. Embodiments relate to an image sensor and a manufacturing method thereof that minimize the occurrence of charge sharing while maximizing a fill factor.

Embodiments relate to an image sensor and a manufacturing method thereof that minimize a dark current source and minimize reduction in saturation and sensitivity by providing a swift movement path for a photo charge between a photodiode and a readout circuitry.

Embodiments relate to an image sensor that may include at least one of the following: a readout circuitry over a first substrate; a first interlayer dielectric over the first substrate; a metal interconnection formed in the interlayer dielectric and electrically connected to the readout circuitry; a top metal over the metal interconnection; and an image sensing device over the top metal.

Embodiments relate to a method for manufacturing an image sensor that may include at least one of the following: forming a readout circuitry on and/or over a first substrate; forming a first interlayer dielectric on and/or over the first substrate; forming a metal interconnection on and/or over the interlayer dielectric; forming a top metal on and/or over the metal interconnection; and forming an image sensing device on and/or over the top metal.

### DRAWINGS

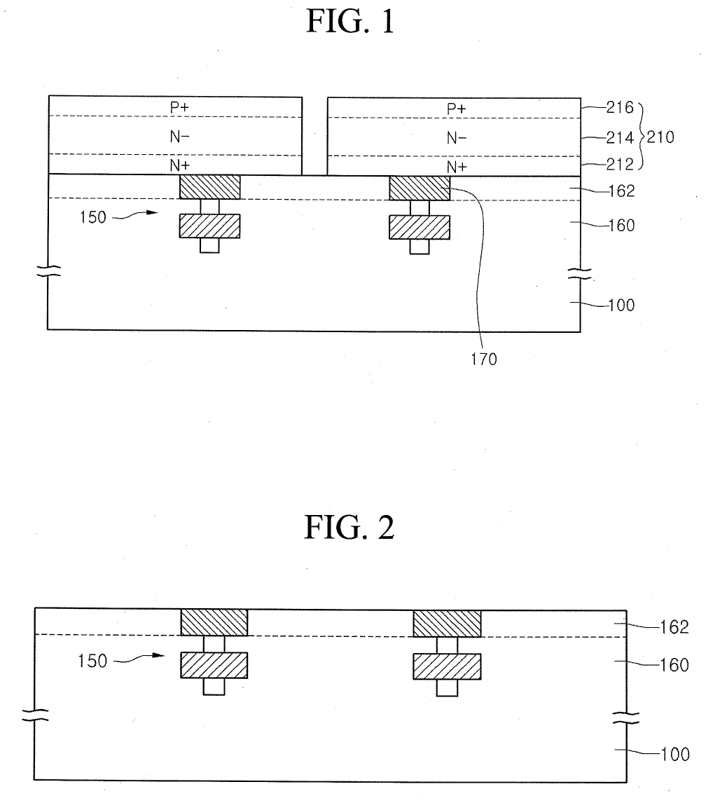

Example FIGS. 1 through 6 illustrate an image sensor and a method for manufacturing an image sensor in accordance with embodiments.

### DESCRIPTION

Example FIG. 1 is a sectional view of an image sensor in accordance with embodiments. As illustrated in example FIG. 1, an image sensor in accordance with embodiments may include: readout circuitry 120 formed on and/or over first substrate 100; first interlayer dielectric 160 formed on and/or over first substrate 100; metal interconnection 150 formed in interlayer dielectric 160 and electrically connected to readout circuitry 120; top metal 170 formed on and/or over metal interconnection 150; and image sensing device 210 formed on and/or over top metal 170. Inage sensing device 210 can be a photodiode, a photogate or any combination thereof. Although embodiments describe a photodiode as being formed in a crystalline semiconductor layer, the photodiode is not limited thereto but may be formed in other ways such as, for example, being formed in an amorphous semiconductor layer.

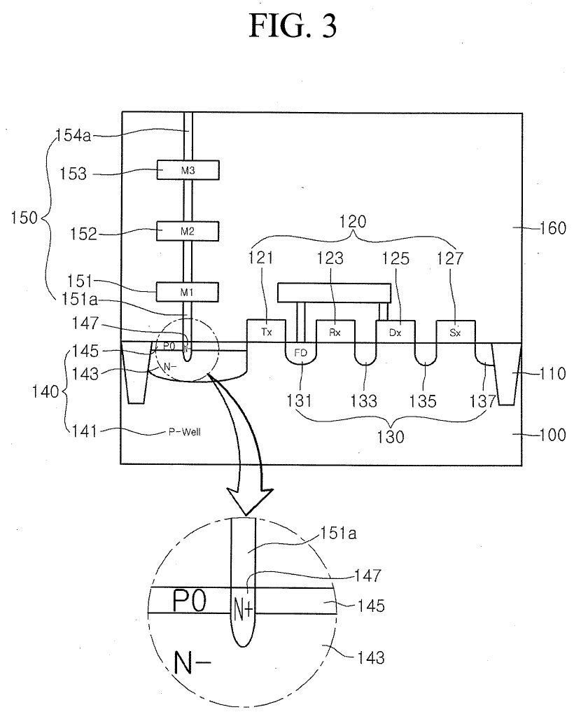

As illustrated in example FIG. 2, first interlayer dielectric 160 may be formed on and/or over first substrate 100, and metal interconnection 150 may be formed in first interlayer dielectric 160. Processes for forming readout circuitry 120 and metal interconnection 150 will be described with reference to example FIG. 3.

As illustrated in example FIG. 3, a method for manufacturing an image sensor in accordance with embodiments may include providing first substrate 100 on, or over, which metal interconnection 150 and readout circuitry 120 are formed. First substrate 100 may be, but is not limited to, a second conduction type substrate. For example, device isolation layer 110 may be formed in second conduction type first substrate 100 to thereby define an active region. Readout circuitry 120 including at least one transistor may be formed in the active region. For example, readout circuitry 120 may include transfer transistor (Tx) 121, reset transistor (Rx) 123, drive transistor (Dx) 125 and select transistor (Sx) 127. Floating diffusion region (FD) 131 of ion implantation regions 130 including source/drain regions 133, 135, and 137 of respective transistors may also be formed.

The forming of readout circuitry 120 on and/or over first substrate 100 may include forming electrical junction region 140 in first substrate 100 and forming first conduction type connection region 147 in an upper region of electrical junction region 140 and electrically connected to metal interconnection 150.

Electrical junction region 140 may be, but is not limited to, a PN junction. For example, electrical junction region 140 may include first conduction type ion implantation layer 143 formed on and/or over second conduction type well 141 or a second conduction type epitaxial layer, and second conduction type ion implantation layer 145 formed on and/or over first conduction type ion implantation layer 143. As illustrated in example FIG. 2, PN junction 140 may be, but is not limited to, a P0 (145)/N− (143)/P− (141) junction.

In accordance with embodiments, a device may be designed such that there is a potential difference between the source and drain on both sides of transfer transistor (Tx) 121 so that a photo charge can be substantially fully dumped. Accordingly, a photo charge generated from the photodiode may be substantially fully dumped to the floating diffusion region so that the sensitivity of an output image can be maximized. Electrical junction region 140 may be formed in first substrate 100 along with readout circuitry 120 to permit generation of a potential difference between the source and the drain on both sides of transfer transistor (Tx) 121 so that a photo charge can be substantially fully dumped.

Unlike a node of floating diffusion (FD) 131, which is an N+ junction, P/N/P junction 140, which is electrical junction region 140 and to which an applied voltage may not be fully transferred, may be pinched-off at a predetermined voltage. This voltage is typically called a pinning voltage, and may be selectively controlled according to the doping concentrations of P0 region 145 and N− region 143. Specifically, an electron generated from the photodiode 210 may move to the PNP junction 140 and may be transferred to the node of floating diffusion (FD) 131 to be converted into a voltage when the transfer transistor (Tx) 121 is turned on.

Because a maximum voltage value of P0/N−/P− junction 140 becomes a pinning voltage, and a maximum voltage value of the node of floating diffusion (FD) 131 becomes a threshold voltage Vₜₕ of V_{dd-Rx} 123, an electron generated from photodiode 210 in the upper portion of a chip can be substantially fully dumped to the node of floating diffusion (FD) 131 without charge sharing by a potential difference between both sides of transfer transistor (Tx) 131.

Meaning, in accordance with embodiments, a P0/N−/P-well junction instead of an N+/P− well junction may be formed in a silicon substrate such as first substrate 100 to allow a positive voltage to be applied to N− 143 of the P0/N−/P-well junction and a ground voltage to be applied to P0 145 and P-well 141 during a 4-Tr active pixel sensor (APS) reset operation. As a result a pinch-off may be generated in the P0/N−/P-well double junction at a predetermined voltage or more as in a bipolar junction transistor (BJT) structure. This is called a pinning voltage. Therefore, a potential difference may be generated between the source and the drain on both sides of transfer transistor (Tx) 121 to prevent a charge sharing phenomenon during the on/off operations of transfer transistor (Tx) 121. Therefore, unlike the case where a photodiode is simply connected to an N+ junction, adverse results such as, for example, saturation reduction and sensitivity reduction can be avoided in accordance with embodiments.

First conduction type connection region 147 may be formed between the photodiode and the readout circuitry to provide a swift movement path of a photo charge, so that a dark current source may be minimized, and saturation reduction and sensitivity reduction can be minimized, or even prevented. For this purpose, first conduction type connection region 147 for ohmic contact can be formed. For example, N+ region 147 can be formed on and/or over the surface of P0/N−/P− junction 140, in accordance with embodiments, and can be formed to extend through P0 region 145 and contact N− region 143.

In order to prevent first conduction type connection region 147 from becoming a leakage source, the width of first conduction type connection region 147 can be minimized. Therefore, in accordance with embodiments, a plug implant can be performed after first metal contact 151a is etched, but other techniques are contemplated as well. For example, an ion implantation pattern may be formed and first conduction type connection region 147 may then be formed using the ion implantation pattern as an ion implantation mask.

One benefit of locally and heavily doping only a contact forming portion with N-type impurities, in accordance with embodiments, is to facilitate ohmic contact formation while minimizing a dark signal. In contrast, heavily doping the entire transfer transistor source, may increase a dark signal because of a Si surface dangling bond.

Interlayer dielectric 160 can be formed on and/or over first substrate 100. Metal interconnection 150 can then be formed extending through interlayer dielectric 160 and electrically connected to first conduction type connection region 147. Metal interconnection 150 can include, but is not limited to, first metal contact 151a, first metal 151, second metal 152, third metal 153 and fourth metal contact 154a.

As illustrated in example FIG. 2, top metal 170 may be formed on and/or over metal interconnection 150. For example, second interlayer dielectric 162 may be formed on and/or over first interlayer dielectric 160, and then a trench may be formed in second interlayer dielectric 162 such that metal interconnection 150 may be exposed. After that, the trench may be filled to form top metal 170. Specifically, a dielectric may be deposited in a thickness range of about 3,000 to about 5,000 Å on and/or over first interlayer dielectric 160, and then a trench photo process may be performed to form a trench pattern on, or over, metal interconnection 150. After that, tungsten (W) or aluminum (Al) may, for example be used to fill trench and then a chemical mechanical polishing (CMP) may be performed to form top metal 170. After that, the resultant first substrate can be bonded to a second substrate functioning as a photodiode.

The bonding between top metal 170 and image sensing device 210 maximizes a contact area between the bonded two substrates, thereby minimizing contact failures; and changes a metal for filling the trench, thereby minimizing contact failures as compared with a contact process using only tungsten (W). Furthermore, because second interlayer dielectric 162 may be formed on and/or over first interlayer dielectric, a planarizing process may be repeated so that any voids generated in bonding of the substrate functioning as a photodiode (PD) due to a height difference due to a test pattern or a photo key on a scribe lane can be controlled, and thus a failure such as a pattern crack can be minimized.

Alternatively, top metal 170 on and/or over metal interconnection 150 may be formed using other techniques as well. For example, first interlayer dielectric 160 may be formed on, or over, first substrate 100, and then a metal layer may be formed on and/or over metal interconnection 150. After that, the metal layer may be selectively etched to form top metal 170 connected to metal interconnection 150. After that, second interlayer dielectric 162 may be formed on and/or over top metal 170 and then second interlayer dielectric 162 may be planarized to expose top metal 170.

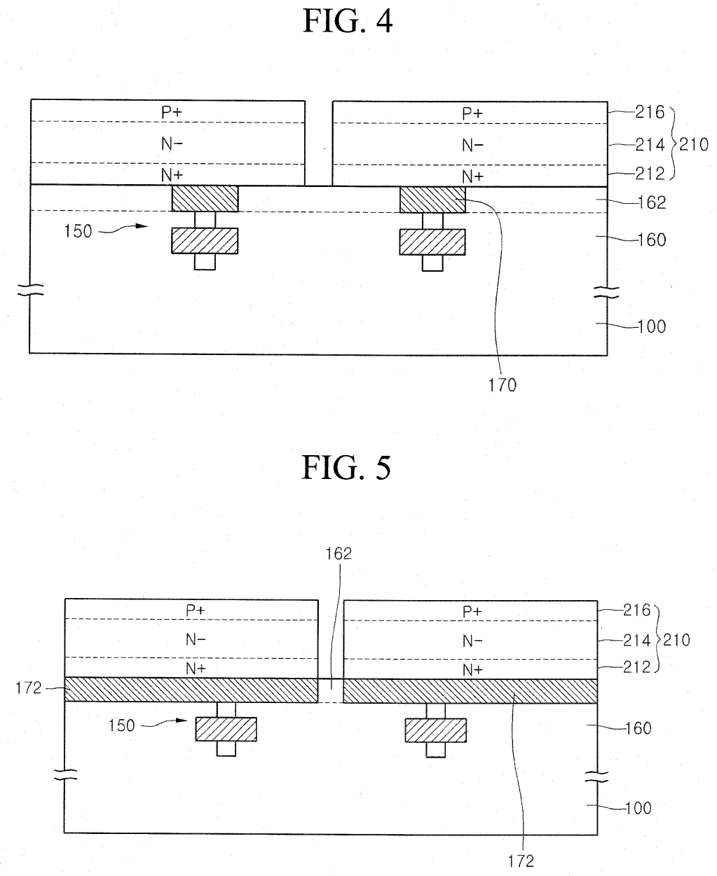

As illustrated in example FIG. 4, image sensing device 210 may be formed on and/or over top metal 170. Image sensing device 210 may, for example, be formed in a crystalline semiconductor layer of a second substrate. Image sensing device 210 may include high concentration first conduction type conduction layer 212, first conduction type conduction layer 214 and high concentration second conduction type conduction layer 216. For example, image sensing device 210 may include N+ layer 212, N− layer 214 and P+ layer 216. N+ layer 212 can contribute to ohmic contact. Because first conduction type conduction layer 214 may be thicker than high concentration second conduction type conduction layer 216, the capacity for capturing photoelectrons can be maximized. An etching process separating image sensing device 210 for each unit pixel can then be performed. The etched portion can then be filled with an interpixel dielectric.

Example FIG. 5 is a sectional view of an image sensor in accordance with embodiments. Embodiments, as illustrated in example FIG. 5, can maximize an electrical contact force because top metal 172 is formed with substantially the same width as the width of image sensing device 210 separated for each unit pixel.

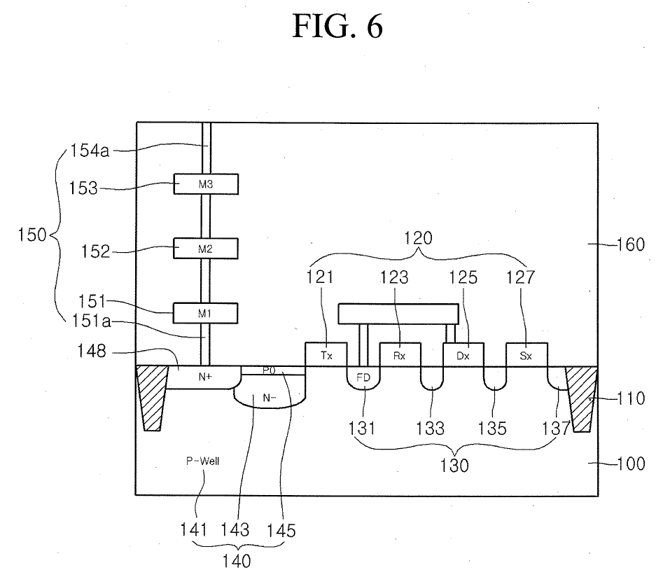

Example FIG. 6 is a sectional view of an image sensor in accordance with embodiments, and is a detailed section view of a first substrate over which metal interconnection 150 may be formed. As illustrated in example FIG. 6, an image sensor in accordance with embodiments may include: readout circuitry 120 formed on and/or over first substrate 100; first interlayer dielectric 160 formed on and/or over first substrate 100; metal interconnection 150 formed in interlayer dielectric 160 and electrically connected to readout circuitry 120; top metal 170 formed on and/or over metal interconnection 150; and image sensing device 210 formed on and/or over top metal 170.

Embodiments, as illustrated in example FIG. 6, may include a top metal interposed between the metal interconnection and the image sensing device to increase a metal contact area, thereby minimizing physical and electrical contact failures. Also, there may be a potential difference between the source and drain on both sides of transfer transistor (Tx), so that a photo charge can be substantially fully dumped. Further, a charge connection region may be formed between a photodiode and the readout circuitry to provide a swift movement path of a photo charge, so that a dark current source is minimized, and saturation reduction and sensitivity reduction can be minimized, or even prevented.

According to example FIG. 6, first conduction type connection region 148 may be formed spaced laterally on and/or over one side of electrical junction region 140. Alternatively, N+ connection region 148 for ohmic contact can be formed on and/or over P0/N−/P− junction 140.

A process of forming N+ connection region 148 and M1C contact 151a may provide a leakage source because the device may operate with a reverse bias applied to P0/N−/P− junction 140 and so an electric field (EF) can be generated on and/or over the Si surface. A crystal defect generated during the contact forming process inside the electric field may serve as a leakage source. Also, with N+ connection region 148 formed on and/or over the surface of P0/N−/P− junction 140, an electric field can be generated due to N+/P0 junction 148/145. This electric field may also serve as a leakage source. Therefore, in accordance with embodiments, a layout may be utilized in which first contact plug 151a may be formed in an active region not doped with a P0 layer but including N+ connection region 148 and may be connected to N-junction 143. Thus, in accordance with embodiments, the electric field may not be generated on and/or over the Si surface, which can contribute to reduction in a dark current of a 3D integrated CIS.

Although embodiments relate generally to a complementary metal oxide semiconductor (CMOS) image sensors, such embodiments are not limited to CMOS image sensors and may be readily applied to any image sensor requiring a photodiode.

It will be obvious and apparent to those skilled in the art that various modifications and variations can be made in the embodiments disclosed. Thus, it is intended that the disclosed embodiments cover the obvious and apparent the modifications and variations, provided that they are within the scope of the appended claims and their equivalents.

What is claimed is:

1. An image sensor comprising:
a readout circuitry over a first substrate;
a first interlayer dielectric over the first substrate;
a metal interconnection formed in the interlayer dielectric and electrically coupled with the readout circuitry;
a top metal over the metal interconnection; and
an image sensing device over the top metal.

2. The image sensor of claim 1, comprising:
a second interlayer dielectric over the first interlayer dielectric and between the image sensing device and the metal interconnection.

3. The image sensor of claim 1, wherein the first substrate includes an electrical junction region electrically coupled with the readout circuitry.

4. The image sensor of claim 3, wherein the electrical junction region comprises:
a first conduction type ion implantation region in the first substrate; and
a second conduction type ion implantation region over the first conduction type ion implantation region.

5. The image sensor of claim 3, wherein the readout circuitry comprises a transistor such that a potential difference exists between a source and a drain on both sides of the transistor.

6. The image sensor of claim 3, wherein the electrical junction region comprises a PN junction.

7. The image sensor of claim 3, comprising:
a first conduction type connection region between the electrical junction region and the metal interconnection.

8. The image sensor of claim 7, wherein the first conduction type connection region is electrically coupled with the metal interconnection.

9. The image sensor of claim 7, wherein the first conduction type connection region is formed spaced from the electrical junction region and electrically coupled with the metal interconnection.

10. The image sensor of claim 1, wherein the image sensing device comprises:
a first conduction type conduction layer and a second conduction type conduction layer over the first conduction type conduction layer, wherein the first conduction type conduction layer is thicker than the second conduction type conduction layer.

11. A method for manufacturing an image sensor, comprising:
forming a readout circuitry over a first substrate;
forming a first interlayer dielectric over the first substrate;
forming a metal interconnection over the interlayer dielectric;
forming a top metal over the metal interconnection; and
forming an image sensing device over the top metal.

12. The method of claim 11, wherein forming the top metal comprises:
forming a second interlayer dielectric over the first interlayer dielectric;
forming a trench in the second interlayer dielectric such that the metal interconnection is exposed; and
filling the trench to form the top metal.

13. The method of claim 11, wherein forming the top metal comprises:
forming a metal layer over the metal interconnection;
forming the top metal by selectively etching the metal layer;
forming a second interlayer dielectric over the top metal; and
planarizing the second interlayer dielectric to expose the top metal.

14. The method of claim 11, comprising:
forming an electrical junction region electrically coupled with the readout circuitry.

15. The method of claim 14, wherein forming the electrical junction region comprises:
forming a first conduction type ion implantation region in the first substrate; and
forming a second conduction type ion implantation region over the first conduction type ion implantation region.

16. The method of claim 14, wherein the readout circuitry comprises:
a transistor such that a potential difference exists between a source and a drain on both sides of the transistor.

17. The method of claim 14, wherein the electrical junction region comprises a PN junction.

18. The method of claim 14, comprising:
forming a first conduction type connection region between the electrical junction region and the metal interconnection.

19. The method of claim 18, wherein the first conduction type connection region is electrically coupled with the metal interconnection.

20. The method of claim 18, wherein the first conduction type connection region is formed spaced from the electrical junction region and electrically coupled with the metal interconnection.
